(19) United States
(12) Patent Application Publication
(10) Pub. No.: US 2022/0193765 A1
(43) Pub. Date: Jun. 23, 2022

(54) STEREOLITHOGRAPHY PROCESS FOR MANUFACTURING A COPPER PART HAVING A LOW RESISTIVITY

(71) Applicant: COMMISSARIAT À L'ÉNERGIE ATOMIQUE ET AUX ÉNERGIES AL TERNATIVES, Paris (FR)

(72) Inventors: Maryline Roumanie, Grenoble (FR); Cécile Flassayer, Grenoble (FR); Denis Vincent, Grenoble (FR)

(21) Appl. No.: 17/602,968

(22) PCT Filed: Apr. 10, 2020
(86) PCT No.: PCT/EP2020/060326

§ 371 Date: Oct. 11, 2021

(30) Foreign Application Priority Data
Apr. 12, 2019 (FR) 1903937

(51) Int. Cl. B22F 1/103; B33Y 10/00; B33Y 70/10; B22F 10/12; B29C 64/165; C09D 4/00; C09D 135/02

(52) U.S. Cl. CPC B22F 1/103; B33Y 10/00; B33Y 70/10; B22F 10/12; B29K 2505/10; C09D 4/00; C09D 135/02; B22F 2201/01; B22F 2201/50; B29C 64/165

(57) ABSTRACT

Process for manufacturing a copper part comprising at least the following successive steps: shaping a part by stereolithography, the shaping being carried out by: forming a layer of paste comprising a powder of copper particles, one or more photopolymerizable precursors of a first resin, a photoinitiator and, optionally, an optical additive, photopolymerizing the photopolymerizable precursor(s) of the first resin, the steps and forming a cycle that can be repeated a plurality of times, carrying out a first heat treatment, under an oxidizing atmosphere containing at least 10 vol % of an oxidizer, such as dioxygen, at a first temperature Td so as to eliminate the first resin, and carrying out a second heat treatment, under a reducing atmosphere, at a second temperature Tf, above the first temperature Td, so as to sinter the copper particles to obtain a copper part.

### TECHNICAL FIELD

The invention relates to a 3D printing method, and in particular a stereolithography method, for manufacturing a copper part.

The invention is particularly interesting since it allows obtaining dense parts, with a complex and/or textured shape, with a very high degree of purity and therefore a low resistivity without increasing the manufacturing costs.

The invention finds applications in many industrial fields, and in particular in the energy field since copper has high thermal (385 W/m.K) and electrical (59.6×106 S.m⁻¹) properties. With such a method, it is possible to design new geometries, for example, to manufacture heat exchangers, or electrical converters.

The invention also relates to a paste for manufacturing copper parts by stereolithography. In particular, the paste allows obtaining parts devoid of cracks, which is particularly advantageous when manufacturing heavy copper parts.

### STATE OF THE ART

Currently, complex-shaped metallic parts are primarily made by additive manufacturing (AM).

Metal additive manufacturing is primarily represented by the technologies of melting on a powder bed: laser melting on a powder bed (or LBM standing for “Laser Beam Melting”) or melting by electron beam on a powder bed (or EBM standing for “Electron Beam Melting”).

However, like any other 3D printing technology by melting, these techniques have the following drawbacks:
the presence of residual stresses in the parts, following the manufacture, which requires carrying out a subsequent heat treatment to relieve the thermomechanical stresses,
local composition modifications by evaporation of elements,
a poor surface quality which requires a polishing step,
a specific grain-size distribution of the powders to carry out an optimum layering, which generates a non-negligible cost in raw material purchase,
management and handling of the powders, during the polishing and cleaning steps, and therefore specific precautions in terms of health, safety and environment.

Finally, sometimes, the laser/material interactions are not effective to manufacture dense parts in particular for copper, a very good heat conductor and reflective material, it is therefore necessary to develop specific machines (laser emitting in the green 520 nm instead of 1064 nm).

In order to overcome these problems, the manufacture of metallic parts by stereolithography (SLA) has expanded. This technique consists in depositing a first paste layer, containing a copper powder, a photopolymerisable resin, and a photoinitiator over a support, and in polymerising this layer in one or more of the selected area(s) by the action of an adequate radiation, UV in general (typically 365 nm). Afterwards, a second layer that is treated according to the same principle is superimposed to this first layer, and these operations are repeated until forming a three-dimensional polymerised part with the desired shape.

The polymer confers a sufficient mechanical strength on the part during manufacture thereof. Afterwards, this polymer is thermally eliminated, during a debinding step, and then, the part is consolidated by sintering. The thermal cycles of debinding and sintering the metals are performed primarily in vacuum, or in argon, to avoid the oxidation of the copper. In comparison with the additive manufacturing by melting on a powder bed, these technologies have the advantage of relying on the know-how of powder metallurgy in terms of debinding/sintering and of being easily integrable by the manufacturers of this field.

In the article of Lee et al. (“Development of micro-stereolithography technology using metal powder”, Microelectronic Engineering 83 (2006) 1253-1256), a formulation charged to 30% by volume with copper particles having a 3 μm diameter is shaped by SLA laser. For example, the formulation may contain as a precursor of an acrylate resin, Ie 1,6-hexanediol diacrylate (HDDA) and trimethylolpropane triacrylate (TMPTA), as a reactive diluent N-vinyl-2-pyrrolidone (NVP) and as a photoinitiator dimethoxy phenylacetophenone (DMPA). A first debinding heat treatment is carried out in vacuum at 600° C. for 1 h and then a second sintering heat treatment is carried out in vacuum at 960° C. for 3 h. The electrical resistivity of the sintered part amounts to 200-300 nOhm.m (namely more than 10 times that of pure copper), which could be caused by a contamination with carbon and/or by the presence of a high porosity.

In the document WO 02/07918 A1, paste compositions containing the precursors of an acrylate resin and a metallic powder are studied. It is indicated that it is preferable to carry out the debinding step in vacuum to limit the stresses at the origin of swelling and cracks. This step may be carried under a reducing gas scavenging to eliminate the carbon residues. It is possible to provide for an additional treatment of dosing the carbonated residues in the presence of an atmosphere containing oxygen, carbon monoxide or carbon dioxide in a controlled manner to avoid the oxidation of the metallic particles since the oxidation of the particles could lead to differential shrinkages and therefore to stresses and distortions. It is also indicated that the sintering step could be carried out in a neutral atmosphere (argon or nitrogen), in a reducing atmosphere or in vacuum. More specifically, in the examples, the debinding step is carried out in primary vacuum (from 10⁻² to 10 mbar) for 40 h and the sintering step is carried out in the presence of argon or in secondary vacuum (10⁻⁶ to 10⁻⁴ mbar). However, such a method is long and difficult to industrialise.

### DISCLOSURE OF THE INVENTION

Consequently, it is an object of the present invention to provide a method for manufacturing a copper part having a low resistivity, the method being simple to implement and industrialisable.

This object is achieved by a method for manufacturing a copper part by 3D printing, in particular by stereolithography, comprising the following successive steps:
a) shaping a part by stereolithography, the shaping being carried out by:
a1) forming a paste layer comprising a powder of copper particles, one or several photopolymerisable precursor(s) of a first resin, a photoinitiator and, possibly, an optical additive,
a2) photopolymerising the photopolymerisable precursor(s) of the first resin, steps a1) and a2) forming a cycle which could be repeated several times,
b) carrying out a first heat treatment, in a first atmosphere, at a first temperature T_{d} so as to eliminate the first resin,
c) carrying out a second heat treatment, in a second atmosphere, at a second temperature T_{f}, higher than the first temperature T_{d}, so as to sinter the copper particles to obtain a copper part,
the first atmosphere consisting of an oxidising atmosphere containing at least 10% by volume of an oxidant, such as dioxygen, and the second atmosphere consisting of a reducing atmosphere.

The invention essentially differs from the prior art by the implementation of a step of debinding in an oxidising atmosphere associated to the implementation of a step of sintering in a reducing atmosphere.

The combination of these two atmospheres leads to a sintered part having a low carbon content and a low oxygen content. The obtained part has a high purity and therefore a low electrical resistivity.

By low carbon content, it should be understood a carbon content lower than 0.1 weight %, and preferably lower than 0.05 weight %, and even more preferably lower than 0.02 weight %.

By low oxygen content, it should be understood an oxygen content lower than 0.1 weight %.

With the methods of the prior art, during the debinding step, the amount of dioxygen is zero or controlled so as to avoid the oxidation of the metallic particles. Hence, resin unburned carbonated residues remain in the part. Hence, the material obtained with such methods is not a pure metal but rather a metal/ceramic or metal/C composite. They do not feature both a low carbon content and a low oxygen content.

In the method of the invention, the debinding step is carried out in an oxidant-rich atmosphere (higher than 10% by volume). Such a step seems to be counterintuitive since it is known that working in an oxidising atmosphere leads to an oxidation of the metals, and therefore to a mechanical fragility of the obtained part and/or to a part having poorer thermal or electrical properties. However, the obtained part has a low resistivity and a very good mechanical strength. Without being bound by theory, it is likely that the organic matrix (resin, photopolymerisable precursor) present in the paste greatly or totally decomposes during the first heat treatment, by formation and degassing of CO or CO₂. The oxygen content present in the part, obtained upon completion of the first heat treatment, is lowered thanks to the second heat treatment in a reducing atmosphere.

By reducing atmosphere, it should be understood an atmosphere containing dihydrogen. The dihydrogen may be used alone or mixed with a so-called neutral gas, such as argon or nitrogen.

By made of copper, it should be understood that the particles consist of copper. Impurities could possibly be present (typically the impurities represent less than 0.2 weight %).

The method for manufacturing a copper part is simple to implement, and does not require accurately monitoring the amount of oxygen. The obtained part is more homogeneous. The stereolithography-type making method, allows making parts with various and complex shapes. In addition, in contrast with the SLM process, the manufacture of the copper parts by SLA does not involve a step of mixing different powders.

Advantageously, the first atmosphere contains at least 15% by volume, and preferably at least 20% by volume of dioxygen.

Advantageously, the first heat treatment is carried out in air, which considerably simplifies the method.

Advantageously, the first heat treatment is carried out at a temperature ranging from 300° C. to 800° C. The debinding temperature T_{d} depends on the implemented binders.

Advantageously, the first heat treatment is carried out for a time period ranging from 2 hours to 7 hours.

Advantageously, the second heat treatment is carried out at a temperature ranging from 980° C. to 1080° C., and advantageously from 980° C. to 1075° C. The sintering temperature of copper is specific, it depends on the method of preparation of the powder, the size of the particles and of the adjuvants that might be added.

Advantageously, the second heat treatment is carried out for a time period ranging from 1 hour to 7 hours, and preferably for a time period ranging from 1 hour to 4 hours.

The extension of the duration of sintering and/or the increase of the sintering temperature allows not only reducing the amount of oxygen present in the part but also obtaining a denser part.

Advantageously, step a2) is carried out with a laser or by digital light processing (DLP). The use of a DLP light source allows illuminating the entire part once for all, which simplifies the process, makes the illumination and therefore the crosslinking more homogenous and improves the production rate.

Advantageously, the paste comprises a tetrafunctional acrylate, a bifunctional acrylate and 2,2-dimethoxy-2-phenylacetophenone. Unexpectedly, it has been observed that with such a paste composition, the part has no or few cracks. Hence, it is possible to make very good quality heavy parts.

Even more advantageously, the tetrafunctional acrylate is di(trimethylolpropane) tetraacrylate and the bifunctional acrylate is bisphenol A ethoxylate dimethacrylate.

Advantageously, the copper powder represents at least 35% by volume of the paste, and preferably from 35% to 65% by volume. The proportion of copper particle powder with respect to the resin will be adjusted according to the pursued mechanical properties of the composite material. The volume percentages should be understood, herein and later on, with respect to the total volume of the paste.

Advantageously, the copper particles have a largest dimension smaller than 45 μm, and preferably smaller than 25 μm.

Advantageously, the optical additive is selected amongst silica, a polythiophene, a polyvinyl alcohol, a polypropylene, and a second resin, crosslinked and ground beforehand. The addition of one of these additives to the paste allows obtaining pastes having a good reactivity (i.e. a reactivity shorter than 30 s, and possibly shorter than 2 s depending on the nature of the optical additive), which allows competing, in terms of production rate, with the SLM-type processes, while avoiding the aforementioned drawbacks of the SLM process.

The invention also relates to a paste, intended to be used in a stereolithography method to manufacturer a copper part, comprising:
a powder of copper particles,
several photopolymerisable precursors of a first resin,
a photoinitiator, and
possibly, an optical additive, selected amongst silica, a polythiophene, a polyvinyl alcohol, a polypropylene, and a second resin, crosslinked and ground beforehand,
the photopolymerisable precursors consisting of a tetrafunctional acrylate and a bifunctional acrylate and the photoinitiator consisting of 2,2-dimethoxy-2-phenylacetophenone.

Advantageously, the tetrafunctional acrylate is di(trimethylolpropane) tetraacrylate and the bifunctional acrylate is bisphenol A ethoxylate dimethacrylate.

Such a paste is particularly interesting for making parts, in particular heavy parts, since the obtained parts have no or very few cracks.

The paste is obtained by mixing in particular the photopolymerisable precursors of the resin, which are viscous, or liquid, and the copper powder, which ensures a perfect homogeneity of the mixture. The steps of handling the powders are reduced and the ecological and health risks related to handling thereof are limited.

Other features and advantages of the invention will come out from the following complementary description.

It goes without saying that this complementary description is provided only to illustrate the object of the invention and should not be interpreted as a limitation of this object.

### BRIEF DESCRIPTION OF THE DRAWINGS

The present invention will be better understood upon reading the description of embodiments provided for merely indicative and non-limiting purposes with reference to the appended drawings wherein:

FIG. 1 is a graph representing the thickness of different paste layers, charged with copper particles, crosslinked at 365 nm as a function of exposure time for different compositions of pastes, according to particular embodiments of the invention,

FIG. 2 represents a 30*30 mm² raw copper part made by SLA, according to a particular embodiment of the invention,

FIGS. 3a and 3b represent a raw copper part (with a photo-crosslinked resin), respectively, before debinding, and after debinding under air and sintering under hydrogen, according to another particular embodiment of the invention,

FIG. 4 represents an optical image in section of a part after debinding under air and sintering under H₂ with a density of 94.5%, according to another particular embodiment of the invention,

FIGS. 5a, 5b, 5c and 5d are photographic images of parts obtained according to different embodiments of the method of the invention.

### DETAILED DISCLOSURE OF PARTICULAR EMBODIMENTS

The invention covers a method for manufacturing a copper part by three-dimensional printing.

The method comprises at least the following successive steps:

Shaping a part by stereolithography, the shaping being carried out by:
a1) forming a paste layer, comprising a copper powder, a photopolymerisable resin, a photoinitiator and, possibly, an optical additive and/or a reactive diluent,
a2) photopolymerising the photopolymerisable precursor(s) of the first resin so as to form the first resin, steps a1) and a2) forming a cycle which could be repeated several times,
b) carrying out a first heat treatment at a first temperature T_{d} on the part so as to eliminate the first resin, in an oxidising atmosphere containing at least 10% by volume of an oxidant,
c) carrying out a second heat treatment, in a reducing atmosphere, at a second temperature T_{f}, higher than the first temperature T_{d}, so as to sinter the copper particles to obtain a copper part.

Shaping of the Part:

The part is shaped, at step a), by stereolithography, i.e. it is obtained by successive polymerisation of several paste layers.

The paste comprises the copper powder, one or several photopolymerisable precursor(s) of a first resin (also called polymer binder or organic binder), one or several photoinitiator(s) and, possibly, an optical additive. The paste is viscous, and possibly liquid, and its constituents are advantageously distributed homogeneously.

The copper powder represents at least 35% by volume to obtain a dense part after heat treatment. Preferably, the powder represents from 35% to 65% by volume, and more preferably from 40% to 65% by volume, and even more preferably from 45% to 65% by volume of the paste. This percentage is also called charge rate. Such charge rates lead to a proper distribution of the powder within the polymer, and to a sufficient amount of precipitate, homogeneously distributed within the copper matrix.

The particles forming the copper powder preferably have a diameter smaller than 50 μm, for example 49 μm, even more preferably smaller than 45 μm, and even more preferably smaller than 30 μm. For example, the particles have a diameter smaller than 25 μm. Advantageously, the copper particles have a diameter larger than 5 μm, for example larger than or equal to 8 μm. For example, the diameter of the particles ranges from 5 μm to 25 μm or from 8 μm to 25 μm. For example, the particles have a diameter of 8 μm, 14 μm or 24 μm.

It is preferable that the size of the particles is smaller than the thickness of the layer formed at step a1).

Preferably, the particles are spherical, on the one hand, to confer a better reactivity on the resin and, on the other hand, to have a final part having a better compactness and a greater density.

Advantageously, the copper particles are stored in a non-oxidising atmosphere before being used. Alternatively, a chemical treatment may be implemented in order to remove the oxide layer that might form at the surface of the copper particles. It is also possible to carry out a heat treatment in a reducing atmosphere at temperatures lower than 500° C., for example for 1 h to 4 h, according to the oxygen content present at the surface of the copper particles.

The copper oxide has a high refractive index (2.6) in comparison with that of acrylate-type resins (1.5). This difference in the refractive index leads to a competition between the UV light absorption by the powder and the activation of the photoinitiators present in the formulation (and therefore the crosslinking of the acrylates). Hence, these phenomena lead to a low reactivity of these charged resins. The non-oxidised copper has a refractive index of 1.3621, close to the resin.

The paste comprises one or several precursor(s) of the first resin. By precursor, it should be understood monomers and/or oligomers and/or pre-polymers leading to the formation of the polymer. For illustration, for the SLA process, mention may be made of the monomers and oligomers of the epoxide (also called “epoxy”), acrylate, urethane acrylate, polyether acrylate, polyether acrylate modified by an amine, epoxy acrylate or polyesteracrylate type.

Advantageously, a functional acrylate, for example an acrylate urethane, a polyetheracrylate modified by an amine, an epoxyacrylate or a polyesteracrylate, or a mixture of these, will be selected. They contribute to wetting of the resin on the particles.

Preferably, the paste comprises a tetrafunctional acrylate such as di(trimethylolpropane) tetraacrylate, and a bifunctional acrylate such as bisphenol A ethoxylate dimethacrylate.

Advantageously, a tetrafunctional acrylate/bifunctional acrylate weight ratio ranging from 1 to 5 and, preferably, from 2 to 4, for example 3, will be selected. The addition of a bifunctional acrylate to a tetrafunctional acrylate allows lengthening the length of the crosslinked chains, limiting shrinkage and therefore obtaining a part without any crack. With such proportions, it is possible to obtain so-called solid parts (typically having a thickness larger than 3 mm), whether apertured or not, such as cylinders.

Advantageously, the paste also comprises an acrylic-type reactive diluent to adjust the viscosity and the crosslinking degree. The acrylic reactive diluent may be a compound as defined in the following formula:

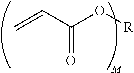

with:
R a polyvalent group, for example, of the hydrocarbon, polyalkylether, or alkoxylated polyol type;
   M an integer, dependent of the group R.

For illustration, the reactive diluent may be selected amongst 1,6-hexanediol diacrylate (HDDA), Trimethylolpropane triacrylate (TMPTA), tripropylglycoltriacrylate (TPGDA), glyceryl propoxylated triacrylate (GPTA).

The paste further comprises one or several polymerisation initiator(s) (also called photoinitiators). In the case of stereolithography, the initiation of the polymerisation of the acrylates is obtained by the absorption of ultraviolet light. The initiators of the acrylates are of the radical type and the selection thereof is primarily guided by the wavelength of the light source they should absorb.

It should be recalled that the UV range goes from a wavelength of 100 nm to 450 nm. UVCs allow crosslinking the materials at surface, UVBs penetrate into the layer and UVAs comprised between 315 nm and 400 nm allow crosslinking a thick layer having, for example, a thickness larger than 20 μm and smaller than 20 mm. In the context of the invention, the light source advantageously has a wavelength set at 365 nm.

Photoinitiators that are suitable for the acrylate-type precursors are from the family of acetophenones, alkoxyacetophenones or phenylacetophenones, such as 2,2′-dimethoxy-2-phenylacetophenone also called DMPA (for example, Irgacure 651 from IGM); from the family of alkylaminoacetophenones or morpholinobutyrophenones such as 2-Benzyl-2-(dimethylamino)-4′-morpholinobutyrophenone (for example, Irgacure 369 from IGM) or 2-Methyl-4′-(methylthio)-2-morpholinopropiophenone (for example, Irgacure 907 de IGM); or from the family of hydroxyalkylphenones such as 2-hydroxy-2-methyl-1-phenyl-propane-1-one (for example, Darocure 1173 from IGM). It could also consist of a phosphine-oxide derivative such as Phenylbis (2,4,6-trimethylbenzoyl) phosphine oxide (for example, Irgacure 819 from CIBA).

Preferably, the photoinitiator is 2,2′-dimethoxy-2-phenylacetophenone. The use of this photoinitiator leads to a more homogeneous crosslinking in the layer and to a lower crosslinking rate. The crosslinking is carried on with temperature at the beginning of debinding, homogenously and without forming any crack.

The optical additive allows scattering and/or reflecting light within the paste layer and thereof improving the reactivity of the resin. For example, the optical additive is selected amongst silica (SiO₂), polysiloxanes, polythiophenes, a resin crosslinked and ground beforehand, polypropylene, polyvinyl alcohol. Preferably, the optical additive is polypropylene or a crosslinked and ground resin.

The polypropylene may be selected from polypropylenes conventionally used for plastics techniques, such as injection. For illustration, it is possible to use a polypropylene commercialised under the name HP500N by the company Basel, a polypropylene commercialised by the company Borealis or Propylmatte 31 from the company Micro Powders.

The polypropylene may be functionalised. For example, it is functionalised with groups allowing for a better scattering of the incident radiation.

Advantageously, when the optical additive is a polymer or a resin, it will be eliminated during the debinding step, which will improve the compactness, the density and the quality of the final part. Preferably, the polypropylene that leaves very little carbonated residues after the debinding step will be selected. Advantageously, the polysiloxane is a wetting agent.

Advantageously, the second resin is of the acrylate type. The second resin is easily eliminated during the heat treatments.

The optical additive represents from 0.1% to 20% by weight with respect to the copper particles to have a dense part. Beyond 20%, after debinding and sintering, a porous part is obtained. With such proportions, the amount of optical additive is sufficient to scatter light and the obtained part has a low porosity.

In the case where the additive is in the form of particles, these preferably have dimensions smaller than that of the particles of the powder to limit porosity in the final parts to have dense parts. For example, the additive particles have a largest dimension at least twice smaller, and preferably ten times smaller, than the largest dimension of the particles of the copper particles. For example, the optical additive particles have dimensions smaller than or equal to 10 μm, for example in the range of 1-2 μm to limit the porosity of the final part or, for example, in the range of 8 μm to have a slightly porous material. Preferably, the optical additive particles have a largest dimension smaller than or equal to 2 μm. The obtained final part has a low porosity.

Other elements may be added to the paste, such as a wetting agent, a rheological agent, etc.

The different constituents are mixed to obtain a homogeneous charged paste. The paste may be homogenised with a paddle mixer.

Advantageously, the threshold behaviour of the paste is of the Herschel Bulkley shear thinner (n<1) or Bingham fluid type.

It will be possible to select a paste having a viscosity higher than 5 Pa.s and preferably higher than or equal to 10 Pa.s at 100 s⁻¹ at 25° C. The paste is easy to spread and sufficiently viscous to form a homogeneous layer. The viscosity of the paste may be measured with a plane/plane or cone/plane type device. For example, the viscosity is measured with a rheometer MCR300.

The viscosity may be adapted according to the machine, for example by adding rheological agents and dispersants.

For illustration, the viscosity of the paste may be measured with a cone/plane head device CP50/1, having a distance between the plates of 100 μm, and by carrying out a pre-shear in 3 min to 2 s⁻¹, then a rise in 5 min with shear rates of 2-200 s⁻¹ and a return in 5 min to 2 s⁻¹.

Advantageously, the paste is prepared at room temperature (20-25° C.).

For example, the paste comprises:
from 80% to 95% and, preferably, from 90% to 95% by weight of copper particles,
from 0,1% to 5% and, preferably, from 0.1% to 1% by weight of one or several photoinitiator(s),
from 2% to 15%, and, preferably, from 2% to 10% by weight of one or several photopolymerisable precursor(s) of a resin, for example a mixture of a tetrafunctional precursor and a bifunctional precursor,
possibly, from 0.1% to 10% and, preferably, from 0.5% to 1% by weight of an optical additive,
possibly, from 1% to 5% and, preferably, from 1 to 2% by weight of a reactive diluent.

The part is made by forming a series of paste layers ranging from 10 μm to 200 μm, and preferably from 25 μm to 200 μm of thickness (step a1), photopolymerised for example with a laser or by a digital light processing (or DLP) (step a2).

Advantageously, step a2) is carried out under UV irradiation for a time period shorter than 30 s, preferably shorter than 10 s, and still more preferably shorter than 2 s.

Advantageously, the paste layer has a thickness ranging from 30 μm to 50 μm and the UV irradiation is carried out for a time period from 0.5 s to 1 s.

The parts formed by SLA may have complex shapes, with cavities of various sizes and shapes.

The part may be shaped, by stereolithography, at room temperature.

The part obtained upon completion of shaping by stereolithography is solid, it comprises a first resin within which the copper powder is dispersed.

Heat Treatments of the Part:

During shaping (step a), the resin serves as a binder to the raw part (also called green part) and ensures cohesion.

Afterwards, this binder is eliminated during the debinding step (step b), to obtain a debound part, called brown part, in the form of a copper skeleton.

Then, the part is sintered to obtain the final part.

The so-called debinding first heat treatment is carried out in an oxidising atmosphere containing at least 10% by volume, preferably, at least 15% by volume and even more preferably at least 20% by volume, of an oxidising element. Preferably, the oxidising element is in a gaseous form. The oxidising element may be dioxygen, carbon monoxide or carbon dioxide. These molecules are introduced in sufficient amounts to allow eliminating the carbonated residues. For example, the oxidising atmosphere is a gaseous mixture containing the oxidant and one or several other gas(es), for example argon and/or nitrogen. The oxidising atmosphere may contain several oxidants, for example dioxygen and carbon dioxide.

Advantageously, the oxidising atmosphere is air.

Advantageously, the first heat treatment is carried out at atmospheric pressure (about 1 bar).

The first heat treatment applied to the part formed by copper particles dispersed in the resin is, advantageously, carried out with low temperature ramps (lower than or equal to 3° C./min, for example in the range of 1° C./min, and possibly lower than 0.1° C./min) to avoid any alteration of the part and the apparition of cracks. Advantageously, such a temperature rise is performed over a rage of 50° C. before the debinding temperature T_{d}. It could also be performed over a wider range, for example over a range, of 100° C., of 200° C. or from the room temperature (20-25° C.) to the debinding temperature. For illustration, if the debinding temperature is 400° C., a low temperature rise, such as a temperature rise of 1° C./min, will be performed from 350° C. to 400° C. It is also possible to perform a very low temperature rise (for example at 0.1° C./min) from the room temperature (25° C.) up to the debinding temperature.

Advantageously, one or several temperature step(s) will be performed before the debinding temperature T_{d}. Advantageously, a step may be performed at T₁=T_{d}−50° C. and/or T₂=T_{d}−100° C. The duration of the steps lasts at least 30 minutes, preferably, at least one hour, and even more preferably at least two hours. The steps may have different durations. For example, for a debinding temperature of 450° C., a first step may be performed at 350° C. for 30 minutes and a second step may be performed at 400° C. for 2 h.

The second heat treatment, called sintering, is carried out in a reducing atmosphere, such as an atmosphere containing dihydrogen. This atmosphere allows reducing the amount of oxygen present in the part upon completion of the debinding step.

The second heat treatment may be carried out at a partial pressure ranging from 50 to 800 mbar.

Advantageously, a temperature step is performed at the sintering temperature T_{f} for a time period of at least 30 minutes and, preferably, for at least one hour, and even more preferably, for a time period of at least two hours.

The debinding T_{d} and sintering T_{f} temperatures will be defined by a person skilled in the art according to the resins.

A person skilled in the art could also select the number of steps as well as the temperature and the duration of the steps. These parameters may also be determined according to the charge rate and the morphology of the powders.

For example, the debinding temperature T_{d} is comprised in the range from 300° C. to 800° C., preferably from 400° C. to 700° C. The debinding temperature is generally determined by thermogravimetric Analysis (TGA) then the step time and ramp cycle is adjusted to limit the cracks due to the off-gases of the binders.

For example, the sintering temperature T_{f} is comprised within the range from 980° C. to 1080° C., and advantageously from 980° C. to 1075° C. Conventionally, the sintering temperature is assessed by dilatometry.

Advantageously, a temperature descending ramp is also performed. For example, it consists of a temperature ramp lower than 5° C./min or according to one variant a temperature ramp from 5 to 10° C./min.

Illustrative and Non-Limiting Example of an Embodiment of a Copper Part by Stereolithography:

First of all, different pastes (formulations) are prepared. The used copper particles are commercialised by the company Ecka and have a grain-size <45 μm.

Formulation 1:
HDDA (Sigma Aldrich) 1.7 weight %
a tetrafunctional oligoacrylate (Sartomer SR355) 4.9 weight %
a trifunctional oligoacrylate (Sartomer CN509) 1.7 weight %
2-methyl-4′-methylthio-2-morpholinopropiophenone (Sigma Aldrich) 0.2 weight %
Phenylbis (2,4,6-trimethyl-benzoyl)phosphine oxide (Sigma Aldrich) 0.2 weight %
90.8 weight % of copper in the resin (namely 54 % vol)
0.5 weight % of an optical additive.

Formulation 2:
HDDA (Sigma Aldrich) 1.3 weight %
a tetrafunctional oligoacrylate (Sartomer SR355) 2.2 weight %
a trifunctional oligoacryalte (Sartomer CN509) 1.3 weight %
an acrylate amine (Sartomer CN371EU) 2.2 weight %
methyl-4′-methylthio-2-morpholinopropiophenone (Sigma Aldrich) 0.2 weight %
Phenylbis (2,4,6-trimethyl-benzoyl)phosphine oxide (Sigma Aldrich) 0.2 weight %
92.2 weight % of copper in the resin (namely 58.6% by volume)
0.5 weight % of an optical additive.

Formulation 3:
HDDA (Sigma Aldrich) 1.5 weight %
a tetrafunctional oligoacrylate (Sartomer SR355) 4.2 weight %
a bifunctional oligoacryalte (Diacryl 101) 1.4 weight %
methyl-4′-methylthio-2-morpholinopropiophenone (Sigma Aldrich) 0.2 weight %
Phenylbis (2,4,6-trimethyl-benzoyl)phosphine oxide (Sigma Aldrich) 0.2 weight %
92.5 weight % of copper in the resin (which corresponds to 60 % vol).

Formulation 4:
HDDA (Sigma Aldrich) 1.5 weight %
a tetrafunctional oligoacrylate (Sartomer SR355) 4.2 weight %
a bifunctional oligoacryalte (Diacryl 101) 1.4 weight %
2-2 Dimethoxy-2-phenyl acetophenone 0.4 weight %
92.5 weight % of copper in the resin (which corresponds to 60 % vol)

The different constituents of the formulations are mixed with a paddle mixer to obtain a homogeneous charged paste.

The developed formulations have a viscosity higher than 5 Pa.s at 100 s⁻¹ with a threshold behaviour.

The manufacture of the different copper parts has been carried out by DLP-type (“digital light processing”) stereolithography, by depositing a first thin paste layer over a support and by polymerising this layer in one or more of the area(s) selected by the action of an adequate radiation, a UV radiation in general. Afterwards, a second layer, also partially or totally polymerised, is deposited over this first layer. These paste deposition/polymerisation cycles are repeated until all of the polymerised portions form the desired part in the raw state.

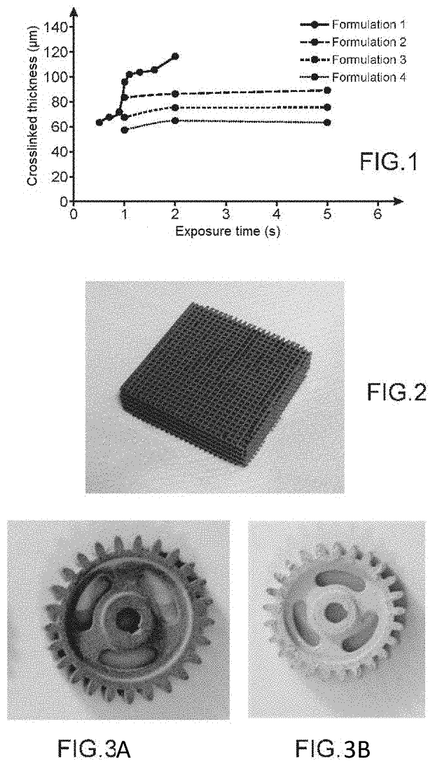

As represented in FIG. 1, according to the composition of the paste, different thicknesses could be crosslinked under UV exposure (365 nm).

For illustration, FIG. 2 represents a 30*30 mm² copper part made by SLA, by depositing paste layers from the formulation 1 with a 45 μm thickness for a crosslinking duration per layer of 0.6 s.

Parts have been manufactured by carrying out a heat treatment of debinding at 400° C. for 4 h in different atmospheres (in vacuum, in hydrogen, in argon, with Ar/O₂ mixtures and in air), then by carrying out a step of sintering in hydrogen at 980° C. for 4 h. The copper particles represent 60% by volume of the paste. The carbon and oxygen content of the different parts have been measured by elementary analysis

(Instrumental Gas Analysis IGA). The results are reported in the following table I:

TABLE I

| | C (%) | N (%) | O (%) |
|---|---|---|---|
| Initial Cu powder | 0.014 | 0.001 | 0.025 |
| Debinding in vacuum | 0.295 | 0.01 | 0.14 |
| Debinding in H₂ | 0.333 | 0.01 | 0.19 |
| Debinding in Ar | 0.394 | 0.006 | 0.077 |
| Debinding in O₂ | 0.483 | 0.005 | 0.074 |
| (600 ppm)/Ar | | | |
| Debinding in O₂ | 0.420 | 0.002 | 0.084 |
| (5% Vol)/Ar | | | |
| Debinding in air | 0.019 | 0.002 | 0.084 |

The debinding atmosphere has a key role on the carbon content in the final part. In air, this content is very low (0.019 weight %) while, for the other conditions, it amounts in average to 0.385 weight %, which is 20 times higher. The carbon content for a part debound in air is close to the carbon content of the starting copper powder.

Table II lists the carbon content and the oxygen content measured for parts obtained with a first heat treatment of debinding in air and a step of sintering in dihydrogen at 400 mbar for different durations and different temperatures.

TABLE II

| Sintering temperature and duration | C (%) | O (%) | Density (%) |
|---|---|---|---|
| 980° C.-4 h | 0.019 | 0.085 | 90 |
| 1030° C.-1 h | 0.017 | 0.077 | 93 |
| 1030° C.-3 h 30 | 0.011 | 0.080 | 93.7 |
| 1050° C.-4 h | 0.018 | 0.067 | 94.5 |

It is possible to lower the oxygen content by increasing the sintering duration and/or temperature, which also allows increasing the density.

FIG. 3A represents a raw copper part, before sintering. FIG. 3B represents the same part after debinding in air and sintering in hydrogen.

The observation of the parts with the optical microscope confirms the high density of the parts (FIG. 4).

Table III lists the carbon, oxygen contents measured for parts obtained with a first heat treatment of debinding, in air at 400° C. for 4 h, and a step of sintering, in dihydrogen at 980° C. for 4 h, for the previously-described 4 formulations.

TABLE III

| | C (%) | O (%) |
|---|---|---|
| Initial Cu powder | 0.014 | 0.025 |
| Formulation 1 | 0.019 | 0.084 |
| Formulation 2 | 0.022 | 0.063 |
| Formulation 3 | 0.018 | 0.054 |
| Formulation 4 | 0.013 | 0.077 |

The parts manufactured from the different formulations have a low content of light elements. The carbon content is similar to that of the initial copper powder.

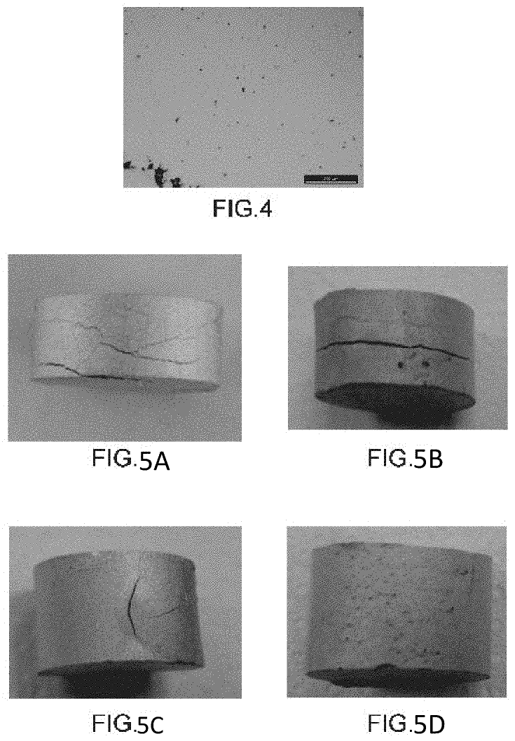

The parts manufactured with this method using the formulations 1, 2, 3 and 4 are represented, respectively, in FIGS. 5a, 5b, 5c and 5d. The parts have a good mechanical strength. More particularly, the formulation 4 leads to a part having a good mechanical strength and devoid of cracks. In addition, the formation 4 does not bring in phosphorous, which leads to a part having good thermal and electrical properties. In particular, the thermal conductivity of the part is identical to that of the pressed and sintered initial powder.

What is claimed is:

1-17. (canceled)

18. A method for manufacturing a copper part comprising at least the following successive steps:
a) shaping a part by stereolithography, the shaping being carried out by:
a1) forming a paste layer comprising a powder of copper particles, one or several photopolymerisable precursor(s) of a first resin and a photoinitiator,
a2) photopolymerising the photopolymerisable precursor(s) of the first resin, steps a1) and a2) forming a cycle which could be repeated several times,
b) carrying out a first heat treatment, in a first atmosphere, at a first temperature T_{d} so as to eliminate the first resin,
c) carrying out a second heat treatment, in a second atmosphere, at a second temperature T_{f}, higher than the first temperature T_{d}, so as to sinter the copper particles to obtain a copper part,
wherein the first atmosphere consists of an oxidising atmosphere containing at least 10% by volume of an oxidant and wherein the second atmosphere consists of a reducing atmosphere.

19. The method according to claim 18, wherein the first atmosphere contains at least 10% by volume of dioxygen.

20. The method according to claim 18, wherein the first atmosphere contains at least 15% by volume of dioxygen.

21. The method according to claim 18, wherein the first atmosphere consists of air.

22. The method according to claim 18, wherein the second atmosphere consists of dihydrogen.

23. The method according to claim 18, wherein the second atmosphere consists of a mixture of dihydrogen and argon.

24. The method according to claim 18, wherein the first heat treatment is carried out at a temperature ranging from 300° C. to 800° C.

25. The method according to claim 18, wherein the first heat treatment is carried out for a time period ranging from 2 hours to 7 hours.

26. The method according to claim 18, wherein the second heat treatment is carried out at a temperature ranging from 980° C. to 1080° C.

27. The method according to claim 18, wherein the second heat treatment is carried out for a time period ranging from 1 hour to 7 hours.

28. The method according to claim 18, wherein the photopolymerisable precursors of the first resin are tetrafunctional acrylate and bifunctional acrylate.

29. The method according to claim 18, wherein the paste comprises a tetrafunctional acrylate, a bifunctional acrylate and 2,2-dimethoxy-2-phenylacetophenone.

30. The method according to claim 28, wherein the tetrafunctional acrylate/bifunctional acrylate weight ratio ranges from 1 to 5.

31. The method according to claim 28, wherein the tetrafunctional acrylate is di(trimethylolpropane) tetraacrylate and wherein the bifunctional acrylate is bisphenol A ethoxylate dimethacrylate.

32. The method according to claim 18, wherein in step a1) the paste layer comprises an optical additive.

33. The method according to claim 32, wherein the optical additive is selected amongst silica, a polythiophene, a polyvinyl alcohol, a polypropylene, and a second resin, crosslinked and ground beforehand.

34. The method according to claim 18, wherein the copper powder represents at least 35% by volume of the paste.

35. A paste, intended to be used in a stereolithography method to manufacture a copper part, comprising:
a powder of copper particles,
photopolymerisable precursors of a first resin,
a photoinitiator, and
wherein the photopolymerisable precursors consist of a tetrafunctional acrylate and a bifunctional acrylate and wherein the photoinitiator consists of 2,2-dimethoxy-2-phenylacetophenone.

36. The paste according to claim 35, wherein the tetrafunctional acrylate/bifunctional acrylate weight ratio ranges from 1 to 5.

37. The paste according to claim 35, wherein the tetrafunctional acrylate is di(trimethylolpropane) tetraacrylate and wherein the bifunctional acrylate is bisphenol A ethoxylate dimethacrylate.
